(19) United States
(12) Patent Application Publication
(10) Pub. No.: US 2022/0037601 A1
(43) Pub. Date: Feb. 3, 2022

(54) FLEXIBLE DISPLAY DEVICE

(71) Applicant: LG Display Co., Ltd., Seoul (KR)

(72) Inventors: Wansoo LEE, Goyang-si (KR); Seungkyu LEE, Bucheon-si (KR); Yeonjae JEONG, Paju-si (KR); JooHye PARK, Anyang-si (KR); NohJin MYUNG, Paju-si (KR); Sejin JANG, Paju-si (KR)

(73) Assignee: LG Display Co., Ltd., Seoul (KR)

(21) Appl. No.: 17/373,459

(22) Filed: Jul. 12, 2021

(30) Foreign Application Priority Data
Jul. 29, 2020 (KR) 10-2020-0094462

(51) Int. Cl. H01L 51/00; H01L 51/52; B32B 17/06

(52) U.S. Cl. CPC H01L 51/0097; H01L 2251/558; B32B 17/06; H01L 51/5246

(57) ABSTRACT

A flexible display device includes a flexible substrate including a display area and a non-display area, an organic light emitting element disposed on the flexible substrate, and a cover member disposed on the organic light emitting element and including a plurality of thin glass plates and an adhesive layer between the plurality of thin glass plates, wherein each of the plurality of thin glass plates has a thickness of 0.1 mm or less. According to an aspect of the present disclosure, it is possible to provide a flexible display device that simultaneously satisfies folding characteristics and impact resistance while maintaining high surface characteristics of glass itself by using a cover member in which the plurality of thin glass plates are stacked.

### CROSS-REFERENCE TO RELATED APPLICATION

This application claims the benefit of and priority to Korean Patent Application No. 10-2020-0094462 filed on Jul. 29, 2020, which is hereby incorporated by reference in its entirety.

### BACKGROUND

### Field of the Disclosure

The present disclosure relates to a flexible display device, and more particularly, to a flexible display device capable of simultaneously improving folding characteristics and impact resistance while using a glass cover member having high surface hardness.

### Description of the Background

Recently, as our society advances toward an information-oriented society, the field of display devices for visually expressing an electrical information signal has rapidly advanced. Various display devices having excellent performance in terms of thinness, lightness, and low power consumption, are being developed correspondingly. Specific examples of such a display device include a liquid crystal display (LCD) device, a plasma display panel (PDP) device, a field emission display (FED) device, an organic light emitting display (OLED) device, and the like.

Recently, shapes and sizes of display devices have been gradually diversified, and in particular, interests in flexible display devices capable of maintaining display performance as they are even when the display devices are bent or folded have continued to increase. Studies and development on a panel, a device, and a cover window having a specific radius of curvature are actively being conducted, correspondingly.

In particular, in the case of a cover window, it is a component exposed to a user in the outside of the display device. Accordingly, it is preferable to use a cover glass having superior exterior characteristics rather than a plastic cover window. Due to properties of glass itself, the cover glass may have folding characteristics when a thickness thereof is 0.1 mm or less. However, although rigidity of the glass itself is considerably superior to that of plastic, its impact resistance is inferior to that of the cover window formed of a plastic material that allows for free design of a thickness. Since it is quite difficult to implement folding characteristics using a cover glass having a general thickness, it is necessary to develop a technology for a cover window that can satisfy both impact resistance and folding characteristics while having excellent surface characteristics.

### SUMMARY

Accordingly, the present disclosure is to provide a flexible display device capable of simultaneously satisfying impact resistance and folding characteristics while using glass having excellent surface characteristics.

The present disclosure is not limited to the above-mentioned features, and other features, which are not mentioned above, can be clearly understood by those skilled in the art from the following descriptions.

A flexible display device according to an exemplary aspect of the present disclosure includes a flexible substrate including a display area and a non-display area; an organic light emitting element disposed on the flexible substrate; and a cover member disposed on the organic light emitting element and including a plurality of thin glass plates and an adhesive layer between the plurality of thin glass plates, wherein each of the plurality of thin glass plates has a thickness of 0.1 mm or less.

Other detailed matters of the exemplary aspects are included in the detailed description and the drawings.

According to the present disclosure, it is possible to provide a flexible display device that simultaneously satisfies folding characteristics and impact resistance while maintaining high surface characteristics of glass itself by using a cover member in which a first thin plate glass and a second thin plate glass are stacked.

In addition, a shatter-resistant layer is disposed on the second thin plate glass, thereby minimizing damage to the cover member due to an external impact, and preventing fragments from shattering in the case of damage occurrence.

In addition, the use of the cover member further including a third thin plate glass provides an effect of further improving impact resistance while maintaining high folding characteristics.

In addition, a thin plate glass at an uppermost portion of the plurality of thin glass plates constituting the cover member may be adhered using a variable adhesive, so that the uppermost thin plate glass may be easily replaced, if necessary, while minimizing damage to a display panel.

In addition, the flexible display device can further include a cushion layer, and in this case, the impact resistance can be further improved while high folding characteristics of the flexible display device are maintained.

According to another exemplary aspect of the present disclosure, since a thin plate glass has a chamfered shape at a corner thereof, folding stress can be more effectively reduced, and thus, a flexible display device having a smaller radius of curvature can be realized.

The effects according to the present disclosure are not limited to the contents exemplified above, and more various effects are included in the present specification.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a cross-sectional view of a flexible display device according to an exemplary aspect of the present disclosure;

FIGS. 2A to 2E are views for explaining various examples of a cover member to which a shatter-resistant layer is applied;

FIG. 3 is a cross-sectional view of a flexible display device according to another exemplary aspect of the present disclosure;

FIG. 4 is a cross-sectional view of a flexible display device according to still another exemplary aspect of the present disclosure;

FIG. 5 is an enlarged view of region A of FIG. 4; and

FIG. 6 is a cross-sectional view of a flexible display device according to yet another exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure can be partially or entirely adhered to or combined with each other and can be interlocked and operated in technically various ways, and the aspects can be carried out independently of or in association with each other.

Hereinafter, a flexible display device according to exemplary aspects of the present disclosure will be described in detail with reference to accompanying drawings.

In describing configurations of the present disclosure, a thin plate glass refers to a glass having a thickness of 0.1 mm or less, unless otherwise specified.

In describing configurations of the present disclosure, a radius of curvature 1R means that a radius of curvature is 1 mm, unless otherwise stated.

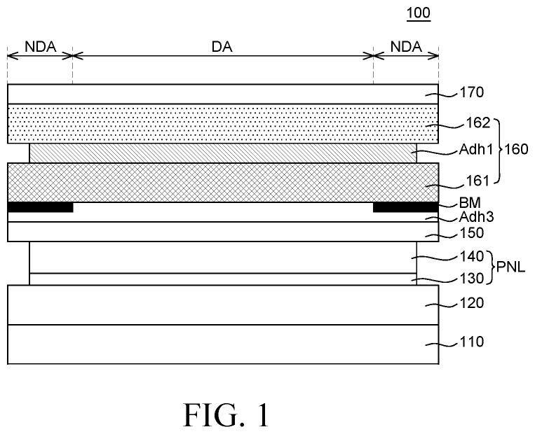

FIG. 1 is a cross-sectional view of a flexible display device according to an exemplary aspect of the present disclosure. Referring to FIG. 1, a flexible display device 100 according to an exemplary aspect of the present disclosure includes a plate assembly 110, a back plate 120, an organic light emitting display panel PNL, an optical control layer 150, a cover member 160, and a shatter-resistant layer 170. The cover member 160 includes a first thin plate glass 161, a first adhesive layer Adh1, and a second thin plate glass 162.

Hereinafter, respective components of the flexible display device according to an exemplary aspect of the present disclosure will be described.

First, the organic light emitting display panel PNL may include a flexible substrate 130 and an organic light emitting element 140.

The flexible substrate 130 is divided into a display area DA and a non-display area NDA. The display area DA is an area where a plurality of pixels are disposed to display an image. Pixels including light emitting areas for displaying an image and driving circuits for driving the pixels may be disposed in the display area DA. The non-display area NDA is disposed to surround the display area DA. The non-display area NDA is an area where an image is not displayed and in the non-display area NDA, various wirings, driver ICs, a printed circuit board and the like for driving the pixels and driving circuits disposed in the display area DA are disposed.

The flexible substrate 130 supports various elements constituting the organic light emitting display panel PNL. The flexible substrate 130 may be a plastic substrate having flexibility. For example, the plastic substrate may be selected from among polyimide, polyethersulfone, polyethylene terephthalate, and polycarbonate, but is not limited thereto. In the case of a plastic substrate, since a barrier property thereof is relatively vulnerable to moisture or oxygen, the plastic substrate may have a structure in which a plastic film and an inorganic film are stacked to compensate for this. For example, the flexible substrate 130 may have a multilayer structure in which a first polyimide film, an inorganic film, and a second polyimide film are sequentially stacked.

The organic light emitting element 140 is disposed on the flexible substrate 130. The organic light emitting element 140 may include an anode, a cathode, and an organic light emitting layer disposed therebetween. The organic light emitting element 140 emits light by combining holes injected from the anode and electrons injected from the cathode in the organic emission layer. An image can be displayed using the light emitted in this manner.

A driving thin film transistor for driving the organic light emitting element 140 is disposed between the flexible substrate 130 and the organic light emitting element 140. The driving thin film transistor may be disposed in each of the plurality of sub-pixel areas. For example, the driving thin film transistor includes a gate electrode, an active layer, a source electrode, and a drain electrode. In addition, the driving thin film transistor may further include a gate insulating layer to insulate the gate electrode and the active layer, and may further include an interlayer insulating layer to insulate the gate electrode, and the source electrode and the drain electrode.

When the flexible display device 100 is folded or bent, it may be difficult to constantly maintain a shape of the organic light emitting display panel PNL having flexibility, and the organic light emitting display panel PNL may be vulnerable to external stimulus.

Accordingly, various types of support members may be disposed on a rear surface of the organic light emitting display panel PNL. For example, the back plate 120 and the plate assembly 110 may be disposed on the rear surface of the organic light emitting display panel PNL.

When the flexible substrate 130 formed of plastic is used, sagging of the organic light emitting display panel PNL may occur when it is folded or bent due to its thin thickness. To compensate for this, the back plate 120 may be disposed on the rear surface of the organic light emitting display panel PNL.

The back plate 120 may be formed of, for example, a metallic material such as stainless steel (SUS) or Invar, and may also be formed of a plastic material such as polymethylmethacrylate (PMMA), polycarbonate (PC), polyvinyl alcohol (PVA), acrylonitrile-butadiene-styrene (ABS), polyethylene terephthalate (PET), silicone, or polyurethane (PU).

The flexible substrate 130 and the back plate 120 may be bonded to each other through, for example, an optical clear adhesive (OCA) or a pressure sensitive adhesive (PSA), but are not limited thereto.

The plate assembly 110 includes a plate top and a plate bottom. The plate top and the plate bottom may be integrally formed, and the plate top or the plate bottom may be omitted if necessary.

The plate bottom may include an opening pattern in a portion thereof corresponding to a folding or bending area of the flexible display device 100. Accordingly, rigidity of the organic light emitting display panel PNL may be enhanced and stress at the time of folding or bending may be effectively alleviated. For example, the plate bottom may be formed of a metallic material such as stainless steel (SUS) or Invar, and may be formed of a plastic material such as polymethylmethacrylate (PMMA), polycarbonate (PC), polyvinyl alcohol (PVA), acrylonitrile-butadiene-styrene (ABS), polyethylene terephthalate (PET), silicone, or polyurethane (PU).

The plate top may be disposed between the back plate 120 and the plate bottom. The plate top may be formed of a material with high rigidity to enhance rigidity of the organic light emitting display panel PNL. Also, the plate top may prevent the opening pattern of the plate bottom from being visually recognized through the organic light emitting display panel PNL. For example, the plate top may be formed of a metallic material such as stainless steel (SUS), Invar, aluminum-based materials or magnesium. As another example, the plate top may be formed of a plastic material such as polymethylmethacrylate (PMMA), polycarbonate (PC) or the like.

The plate assembly 110 may be bonded to a rear surface of the back plate 120 through an optical clear adhesive (OCA) or a pressure sensitive adhesive (PSA).

The optical control layer 150 is disposed on the organic light emitting display panel PNL. The optical control layer 150 may uniformly transmit light emitted from the organic light emitting display panel PNL to the outside without reducing luminance of the flexible display device 100 and absorb or reflect external light to thereby improve display quality.

The optical control layer 150 may be bonded to an upper portion of the organic light emitting display panel PNL through an optical clear adhesive (OCA) or a pressure sensitive adhesive (PSA).

The cover member 160 is disposed on the optical control layer 150. The cover member 160 protects the organic light emitting display panel PNL from being damaged by an external impact. In addition, the cover member 160 may be bonded onto the optical control layer 150 through an optical clear adhesive (OCA) or a pressure sensitive adhesive (PSA), but is not limited thereto.

For example, the cover member 160 includes a first thin plate glass 161, a first adhesive layer Adh1, and a second thin plate glass 162.

The first thin plate glass 161 may have a thickness of, for example, 0.1 mm or less, 90 μm or less, 50 μm to 0.1 mm, 50 μm to 90 μm, or 70 μm to 90 μm. The thin plate glass having such a limited thickness can effectively alleviate stress applied when the flexible display device 100 is folded or bent.

The first thin plate glass 161 is disposed between the second thin plate glass 162 and the organic light emitting display panel PNL and functions to directly protect the organic light emitting display panel PNL.

A black matrix layer BM may be formed on an upper surface or a lower surface of the first thin plate glass 161 that corresponds to the non-display area NDA. The black matrix layer BM includes a material that absorbs light, for example, a light-absorbing metal, carbon black, or black resin. Accordingly, components such as wirings disposed in the non-display area NDA are prevented from being visually recognized to the outside. In addition, the black matrix layer BM functions to prevent light leakage at a side surface of the flexible display device 100.

The second thin plate glass 162 is stacked on the first thin plate glass 161. The second thin plate glass 162 is a component directly exposed to the outside and protects the organic light emitting display panel PNL from external impacts.

For example, a thickness of the second thin plate glass 162 may be 0.1 mm or less, 90 μm or less, 50 μm to 0.1 mm, 50 μm to 90 μm, or 70 μm to 90 μm. The thin plate glass having such a limited thickness can effectively alleviate stress applied when the flexible display device 100 is folded or bent.

As another example, the thickness of the second thin plate glass 162 may be identical to or different from the thickness of the first thin plate glass 161. For example, the thickness of the first thin plate glass 162 may be 0.1 mm or less or 70 μm to 0.1 mm, and the thickness of the second thin plate glass 161 may be 70 μm or less or 50 μm to 70 μm.

When the flexible display device 100 is folded or bent, the second thin plate glass 162 that is stacked on the first thin plate glass 161 may receive relatively greater stress than the first thin plate glass 161. Accordingly, in order to reduce folding stress, the second thin plate glass 162 may be formed to have a thickness smaller than that of the first thin plate glass 161. In general, as a thickness of glass decreases, impact resistance tends to decrease. However, the cover member 160 according to an exemplary aspect of the present disclosure has a structure in which the first thin plate glass 161 and the second thin plate glass 162 are stacked, so it is possible to effectively reduce folding stress while maintaining high impact resistance.

The first thin plate glass 161 and the second thin plate glass 162 may be chemically strengthened glass. Chemically strengthened glass is a glass of which strength is strengthened by a chemical strengthening method. The chemical strengthening method is a process of strengthening the strength of glass by an ion exchange method in which sodium ions contained in the glass are substituted with ions having a larger ionic radius. In accordance with penetration of ions with an ionic radius larger than the sodium ions constituting the glass, a compressive stress layer is formed on a surface of the glass, so that the strength can be strengthened.

For example, chemically strengthened glass may be that manufactured by a process of immersing the glass in a potassium salt solution such as potassium nitrate and substituting the sodium ions of the glass with potassium ions while heating the glass at 200° C. to 450° C., which is below a glass transition temperature for a predetermined period of time, but is not limited thereto.

When the chemically strengthened glass as described above is used as the first thin plate glass 161 and the second thin plate glass 162, impact resistance can be further improved while maintaining high folding characteristics. Since the second thin plate glass 162 is exposed to the outside of the flexible display device 100, chemically strengthened glass may be used to secure scratch resistance and prevent dents during folding or bending.

The first adhesive layer Adh1 is disposed between the first thin plate glass 161 and the second thin plate glass 162 to bond them. The first adhesive layer Adh1 may be a variable adhesive. That is, the first thin plate glass 161 is fixedly adhered to the optical control layer using an optical clear adhesive (OCA) or a pressure sensitive adhesive (PSA), and the second thin plate glass 162 is adhered to the first thin plate glass 161 using the variable adhesive. As described above, when the second thin plate glass 162 is bonded to the first thin plate glass 161 through the variable adhesive, the second thin plate glass 162 can be easily replaced by lowering adhesion if necessary.

For example, the variable adhesive may be an optically variable adhesive or a thermally variable adhesive. The optically variable adhesive has adhesion that varies according to presence or absence of UV irradiation, so that the second thin plate glass 162 can be replaced by lowering the adhesion if necessary.

The thermally variable adhesive has adhesion that decreases in a specific temperature range, or has adhesion that decreases due to expansion of a thermally expandable material under specific temperature conditions by including the thermally expandable material. Accordingly, if necessary, the second thin plate glass 162 can be easily replaced.

As another example, the variable adhesive may be an adhesive which may be removed by moisture (hereinafter, referred to as “moisture-removable adhesive”). The moisture-removable adhesive has adhesion which is variable according to presence or absence of moisture. For example, the moisture-removable adhesive includes an acrylic-based resin, and surfactants such as fatty acids, straight chain alkylbenzenes, higher alcohols, alkylphenols, alpha-olefins, normal paraffins, alkylglucosides, sucrose fatty acid esters, sorbitan fatty acid esters, polyoxyethylene sorbitan fatty acid esters, and the like. These surfactants contain a hydrophilic group and can interact with water. Accordingly, when moisture is added to the moisture-removable adhesive, the surfactant having a hydrophilic group migrates to a surface of the adhesive, and thus, a decrease in adhesion is caused. Using these properties, the first thin plate glass 161 and the second thin plate glass 162 can be separated by adding moisture to the moisture-removable adhesive, and the second thin plate glass 162 can be easily replaced if necessary.

For example, the variable adhesive has an adhesion of 1 kgf/inch or more in a state in which the first thin plate glass 161 and the second thin plate glass 162 are bonded, and the adhesion can be lowered to 100 gf/inch or less in a reworking process for replacing the second thin plate glass 162. In this case, even when the flexible display device 100 is folded/bent, slip or peeling of each layer can be prevented, and the adhesion is greatly reduced during the reworking process, so that the second thin plate glass 162 may be replaced while the organic light emitting display panel PNL is not damaged.

The shatter-resistant layer 170 may be disposed on the second thin plate glass 162. The shatter-resistant layer 170 may act as a buffer to prevent damage to the first thin plate glass 161 and the second thin plate glass 162 from external impacts, and to prevent fragments from shattering when damage occurs.

For example, the shatter-resistant layer 170 may include polyurethane or a silicone-based resin, which may well absorb an external impact, while suppressing the spread of fragments when glass is broken.

For example, the shatter-resistant layer 170 may be formed by coating a shatter-resistant coating agent on an upper surface of the second thin plate glass 162. Specifically, the shatter-resistant coating agent may be applied to the upper surface of the second thin plate glass 162 by a general method, and then, cured to thereby form the shatter-resistant layer 170. In this case, the shatter-resistant layer 170 may be directly formed on the second thin plate glass 162 without using a separate adhesive. However, the present disclosure is not limited thereto.

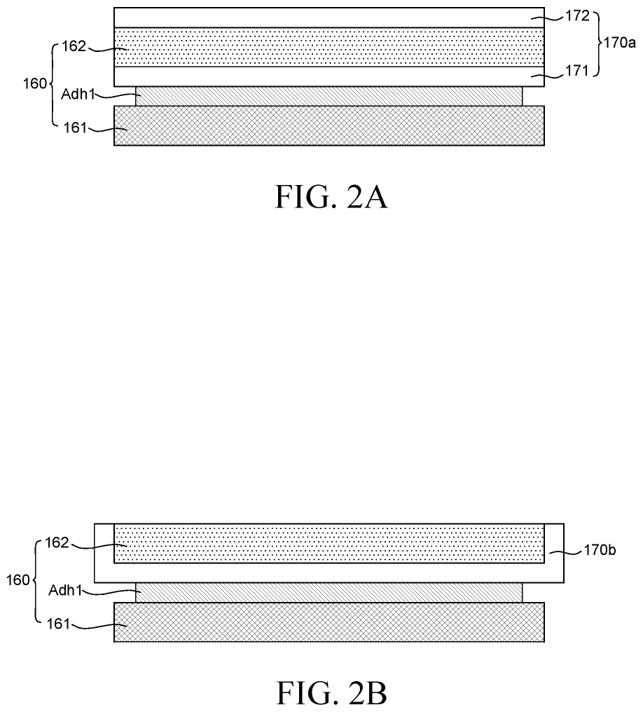

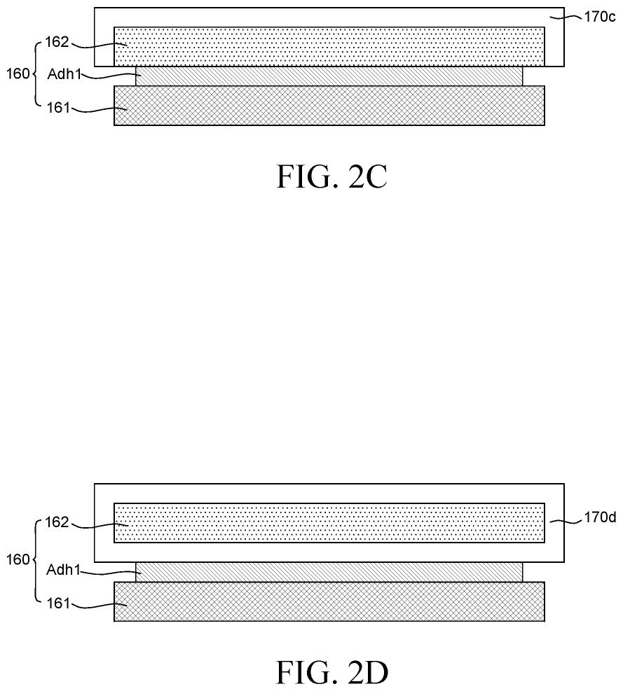

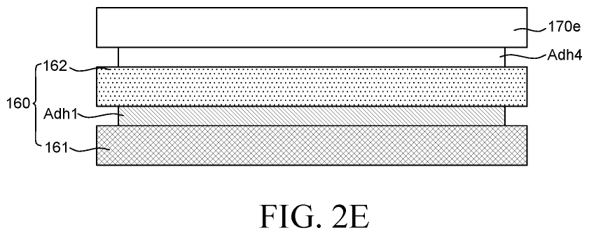

Hereinafter, a structure of the shatter-resistant layer will be described in more detail with reference to FIGS. 2A to 2E.

FIGS. 2A, 2B, 2C, 2D and 2E are views showing various examples of applying shatter-resistant layers to the cover member. In FIGS. 2A, 2B, 2C, 2D and 2E, only the first thin plate glass, the second thin plate glass, the first adhesive layer, and the shatter-resistant layer are illustrated for convenience of explanation.

Referring to FIG. 2A, a first shatter-resistant layer 171 may be formed on a lower surface of the second thin plate glass 162, and a second shatter-resistant layer 172 may be formed on the upper surface of the second thin plate glass 162. Accordingly, an external impact can be more effectively absorbed, and shattering of fragments when damage occurs can be prevented. The first shatter-resistant layer 171 and the second shatter-resistant layer 172 may be formed by coating the same shatter-resistant coating agent, or may be formed by coating different coating agents if necessary. For example, the second shatter-resistant layer 172 may be formed by using a shatter-resistant coating agent that can more effectively prevent fragments from shattering when the cover member 160 is damaged, and the first shatter-resistant layer 171 may be formed using a shatter-resistant coating agent with excellent buffering properties to more effectively absorb impacts applied from the outside.

Referring to FIG. 2B, a shatter-resistant layer 170b may be formed to surround side surfaces and the lower surface of the second thin plate glass 162. As such, when the shatter-resistant layer 170b is formed to surround the side surfaces and the lower surface of the second thin plate glass 162, there are advantages in that scratch resistance and exterior characteristics are better because the glass with high surface hardness is exposed to the surface while absorbing external impacts well.

Referring to FIG. 2C, a shatter-resistant layer 170c may be formed to surround the upper surface and the side surfaces of the second thin plate glass 162. In this case, when the second thin plate glass 162 is damaged due to an external impact, it is possible to more effectively restrain shattering of the fragments.

Referring to FIG. 2D, a shatter-resistant layer 170d may be formed to surround all of the upper surface, the lower surface, and the side surfaces of the second thin plate glass 162. In this case, since the shatter-resistant layer 170d completely surrounds all surfaces of the second thin plate glass 162, effects of absorbing impacts and preventing the shattering of fragments can be maximized.

Referring to FIG. 2E, the shatter-resistant layer 170e may be bonded to the upper surface of the second thin plate glass 162 through a separate adhesive layer Adh4. That is, without using a shatter-resistant coating agent, a shatter-resistant film is adhered to the upper surface of the second thin plate glass 162 by using the adhesive layer Adh4 to thereby form the shatter-resistant layer 170e. In this case, the shatter-resistant layer 170e may have a thickness greater than that of a shatter-resistant layer formed by using the shatter-resistant coating agent. Accordingly, external impact absorption can be effective, and when the cover member 160 is damaged, it is possible to prevent a sharp side of the glass from protruding.

Various functional layers may be selectively disposed between the second thin plate glass 162 and the shatter-resistant layer 170 or on an upper portion of the shatter-resistant layer 170, as needed.

For example, the functional layers may be selected from among a hard coating layer, an anti-fingerprint layer, an anti-reflection layer, a contamination prevention layer, an anti-glare layer, a viewing angle control layer, an anti-static layer, and the like, and may be variously combined according to required physical properties.

The flexible display device according to an exemplary aspect of the present disclosure have improved impact resistance and folding characteristics by using the cover member in which thin glass plates are stacked, while maintaining intrinsic high surface characteristics of glass.

For example, the flexible display device 100 according to an exemplary aspect of the present disclosure can be implemented with a radius of curvature of 30R or less, 10R or less, or 5R or less, and can have impact resistance equivalent to or greater than that of a conventional cover glass to which a single glass is applied, while having excellent folding characteristics.

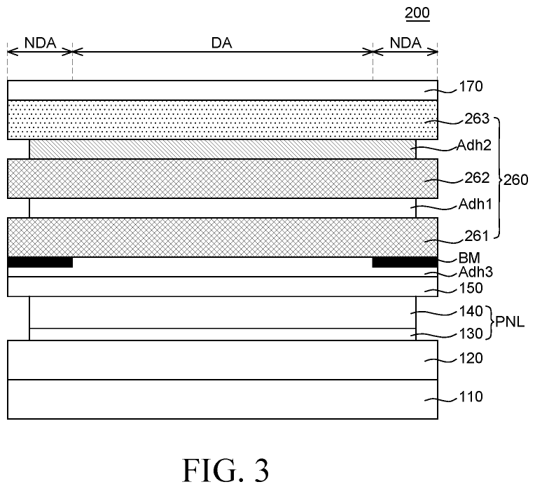

FIG. 3 is a cross-sectional view of a flexible display device according to another exemplary aspect of the present disclosure. Referring to FIG. 3, a flexible display device 200 according to another exemplary aspect of the present disclosure is substantially identical to the flexible display device 100 illustrated in FIG. 1, except that the flexible display device 200 includes a cover member 260 further including a third thin plate glass 263 and a second adhesive layer Adh2. Therefore, a redundant description will be omitted.

The cover member 260 has a structure in which a first thin plate glass 261, a first adhesive layer Adh1, a second thin plate glass 262, a second adhesive layer Adh2, and a third thin plate glass 263 are sequentially stacked. The flexible display device 200 shown in FIG. 3 provides effects of allowing for more excellent impact resistance while having folding characteristics equivalent to or greater than those of the flexible display device 100 shown in FIG. 1 by using the cover member 260 that further includes one thin plate glass compared to the flexible display device 100 shown in FIG. 1.

In the flexible display device 200 according to another exemplary aspect of the present disclosure, the first thin plate glass 261 and the second thin plate glass 262 have the same characteristics as the first thin plate glass 161 described with reference to FIG. 1.

The first thin plate glass 261 and the second thin plate glass 262 are bonded to each other by the first adhesive layer Adh1. For example, the first adhesive layer Adh1 may include an optical clear adhesive (OCA) or a pressure sensitive adhesive (PSA).

For example, a thickness of each of the first thin plate glass 261 and the second thin plate glass 262 may be 0.1 mm or less, 90 μm or less, 50 μm to 0.1 mm, 50 μm to 90 μm, or 70 μm to 90 μm. The thin plate glass having such a limited thickness can effectively alleviate stress applied when the flexible display device 200 is folded or bent.

The third thin plate glass 263 is disposed on the second thin plate glass 262. In the flexible display device 200 according to another exemplary aspect of the present disclosure, the third thin plate glass 263 has the same characteristics as the second thin plate glass 162 described above with reference to FIG. 1.

A thickness of the third thin plate glass 263 may be, for example, 0.1 mm or less, 90 μm or less, 50 μm to 0.1 mm, 50 μm to 90 μm, or 70 μm to 90 μm. When the flexible display device 200 is folded or bent, the third thin plate glass 263 stacked at an uppermost portion of the thin glass plates receives relatively greater stress than the first thin plate glass 261 or the second thin plate glass 262. Accordingly, in order to reduce folding stress, the third thin plate glass 263 may have a thickness smaller than those of the first thin plate glass 261 and the second thin plate glass 262.

The sum of the respective thicknesses of the plurality of thin glass plates may be 0.3 mm or less. For example, the sum of the respective thicknesses of the first thin plate glass 261, the second thin plate glass 262, and the third thin plate glass 263 may be 0.3 mm or less, 0.1 mm to 0.3 mm, 0.25 mm or less, 0.1 mm to 0.25 mm or 0.2 mm or less. In general, impact resistance and folding characteristics are in a trade-off relationship, and it is difficult to satisfy both of these conditions. However, when the plurality of thin glass plates are stacked within a range in which the sum of thicknesses is 0.3 mm or less, it is possible to break the trade-off relationship between impact resistance and folding characteristics and satisfy both conditions at the same time.

The third thin plate glass 263 is bonded to the second thin plate glass 262 by the second adhesive layer Adh2. In this case, the second adhesive layer Adh2 may include a variable adhesive. That is, the first thin plate glass 261 is fixedly adhered onto the optical control layer using an optical clear adhesive (OCA) or a pressure sensitive adhesive (PSA), the second thin plate glass 262 is also fixedly adhered onto the first thin plate glass 261 using an optical clear adhesive (OCA) or a pressure sensitive adhesive (PSA), and the third thin plate glass 263 is adhered onto the second thin plate glass 262 using the variable adhesive. Accordingly, in a reworking process, the adhesion of the second adhesive layer Adh2 is lowered, so that the third thin plate glass 263 can be easily separated from the second thin plate glass 262. Accordingly, if necessary, the third thin plate glass 263 can be easily replaced without damage to the organic light emitting display panel PNL. However, the present disclosure is not limited thereto.

For example, both the first adhesive layer Adh1 and the second adhesive layer Adh2 may include the variable adhesive. Accordingly, not only the third thin plate glass 263 but also the second thin plate glass 262 may be replaced through a reworking process if necessary.

As described above, the variable adhesive may be selected from among the optically variable adhesive, the thermally variable adhesive, or the moisture-removable adhesive.

The shatter-resistant layer 170 may be disposed on the third thin plate glass 263.

A functional layer that is selected from among a hard coating layer, an anti-fingerprint layer, an anti-reflection layer, a contamination prevention layer, an anti-glare layer, a viewing angle control layer, an anti-static layer, or the like, may be disposed between the shatter-resistant layer 170 and the third thin plate glass 263 or on the shatter-resistant layer 170.

The flexible display device 200 according to another exemplary aspect of the present disclosure provides advantages of further improving impact resistance while maintaining high folding/bending characteristics by using the cover member 260 in which the first thin plate glass 261, the second thin plate glass 262, and the third thin plate glass 263 are stacked.

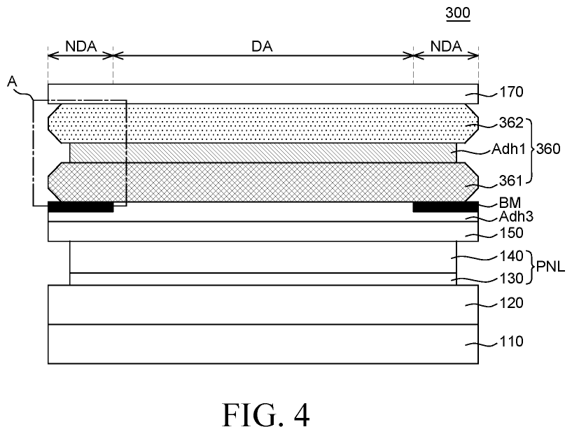

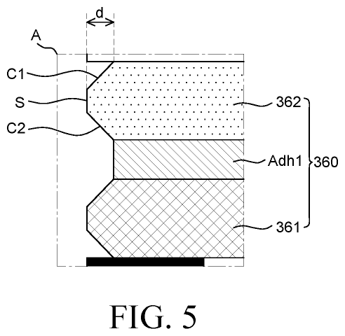

FIG. 4 is a cross-sectional view of a flexible display device according to still another exemplary aspect of the present disclosure. FIG. 5 is an enlarged view of region A of FIG. 4.

A flexible display device 300 shown in FIG. 4 is substantially identical to the flexible display device 100 shown in FIG. 1, except for shapes of a first thin plate glass 361 and a second thin plate glass 362. Therefore, descriptions overlapping those described above will be omitted.

Referring to FIG. 4, each of the first thin plate glass 361 and the second thin plate glass 362 may have a chamfered shape at corners thereof. Each of the first thin plate glass 361 and the second thin plate glass 362 has a chamfered shape at each of upper corners and lower corners thereof. As described above, when the first thin plate glass 361 and the second thin plate glass 362 have a chamfered shape, folding stress that is more concentrated on edge portions thereof at the time of folding or bending may be reduced, and folding characteristics of the flexible display device 300 can be further improved.

The chamfered shape may be formed by performing etching to a predetermined depth from a glass surface at a side surface of the glass. For example, the first thin plate glass 361 and the second thin plate glass 362 having a chamfered shape may be formed through a healing process of chemically etching the glass. Specifically, after stacking thin glass plates that are cut in cell units in multiple layers, when attaching a protective layer, for example, a dummy film to upper and lower surfaces of the stacked glasses and then, immersing them in an etchant, the etching occurs on the side surfaces of the glasses exposed to the etchant. In addition, the etchant penetrates into a gap between the stacked glasses, so that each of the stacked thin glass plates has a chamfered shape on the side surfaces thereof.

Hereinafter, the chamfered shape will be described in detail with reference to FIG. 5.

As described above, through the healing process, the glass is etched to a predetermined depth from the glass surface at a side portion of the thin plate glass and thus, has a chamfered shape. Accordingly, the second thin plate glass 362 includes a first inclined portion C1 formed by etching from an upper surface thereof to a predetermined depth and a second inclined portion C2 formed by etching from a lower surface thereof to a predetermined depth.

The first inclined portion C1 connects the upper surface and a side surface S of the second thin plate glass 362, and the second inclined portion C2 connects the lower surface and the side surface S of the second thin plate glass 362. An inclination angle by the first inclined portion C1 and an inclination angle by the second inclined portion C2 may be 10° to 60° or 20° to 50°, but are not limited thereto.

A linear distance d from an end of the upper surface of the second thin plate glass 362, that is, a portion where first inclined portion C1 and the upper surface contacts, to the side surface S of the second thin plate glass 362, that is, a portion where the first inclined portion C1 and the side surface S contacts, may be 10 μm to 50 μm. Within this range, folding stress concentrated on the edge portion of the second thin plate glass 362 can be effectively reduced, so that folding characteristics are further improved.

The first thin plate glass 361 may also have a chamfered shape to include the first inclined portion and the second inclined portion in the same manner as the second thin plate glass 362, and a redundant description thereof will be omitted.

As described above, by forming the chamfered shape at the corners of each of the first thin plate glass 361 and the second thin plate glass 362, folding stress is reduced at the edge portions when the flexible display device 300 is folded or bent, so that folding characteristics can be greatly improved, and at the same time, impact resistance is improved.

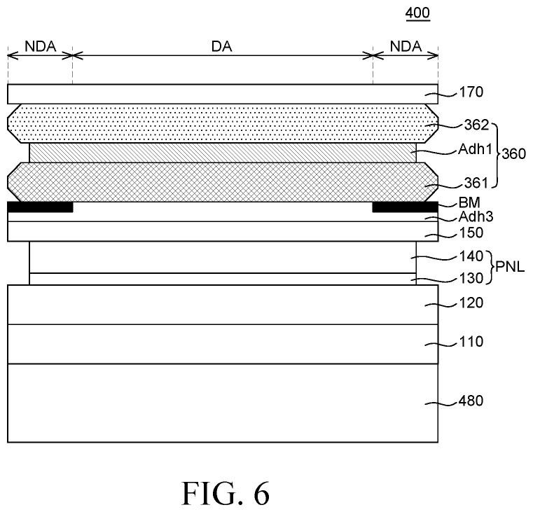

FIG. 6 is a cross-sectional view of a flexible display device according to yet another exemplary aspect of the present disclosure.

Referring to FIG. 6, a flexible display device 400 according to yet another exemplary aspect of the present disclosure is substantially identical to the flexible display device 300 shown in FIG. 4, except that the flexible display device 400 further includes a cushion layer 480. Accordingly, a redundant description will be omitted.

The cushion layer 480 is disposed under the plate assembly. The cushion layer 480 may minimize transmission of an external impact to the organic light emitting display panel PNL. The cushion layer 480 may be formed of a polymer material having excellent impact absorption properties, such as silicone gel, silicone foam, acrylic foam, polypropylene foam, polyurethane, polyurethane foam, thermoplastic polyurethane, but is not limited thereto.

When a thickness of the cushion layer 480 is too small, impact absorption force is insufficient, and when the thickness is too large, folding or bending of the flexible display device 400 may be difficult. For example, the cushion layer 480 may have a thickness of 100 μm to 1000 μm, but is not limited thereto.

The flexible display device 400 of the present disclosure includes a cover member 360 in which the first thin plate glass 361 and the second thin plate glass 362 are stacked, and can effectively absorb impacts applied from an upper portion and a lower portion of the flexible display device 40 by the cover member 360 and the cushion layer 480, while maintaining high folding characteristics, thereby providing a synergistic effect of further improving impact resistance.

Hereinafter, the effects of the present disclosure described above will be described in more detail through Examples and Comparative Examples. However, the following examples are for illustration of the present disclosure, and the scope of the present disclosure is not limited by the following examples.

### Example 1

A flexible display device as shown in FIG. 4 was manufactured by sequentially stacking a cushion layer (silica gel), a plate bottom, a polyimide film, a driving thin film transistor and an organic light emitting element, a polarizing film, a first thin plate glass (70 μm) and a second thin plate glass (70 μm).

### Example 2

A flexible display device was manufactured in the same manner as in Example 1, except that a retardation film (NRF) was additionally stacked on the second thin plate glass.

### Example 3

A flexible display device was manufactured in the same manner as in Example 1, except that a third thin plate glass (70 μm) was additionally stacked on the second thin plate glass.

### Example 4

A flexible display device was manufactured in the same manner as in Example 2, except that a third thin plate glass was further included between the second thin plate glass and the retardation film (NRF).

### Comparative Example 1

A display device was manufactured by sequentially stacking a plate bottom, a plate top (SUS), a polyimide film, a driving thin film transistor and an organic light emitting element, a polarizing film, and a film-type cover window.

### Comparative Example 2

A flexible display device was manufactured in the same manner as in Example 1, except that the second thin plate glass in Example 1 was omitted, and a cover member formed of a single layer of the first thin plate glass (70 μm) was used.

### Comparative Example 3

A flexible display device was manufactured in the same manner as in Example 1, except that the second thin plate glass in Example 1 was omitted, and a cover member formed of a single layer of the first thin plate glass (100 μm) was used.

### Comparative Example 4

A flexible display device was manufactured in the same manner as in Example 1, except that the second thin plate glass in Example 1 was omitted, and a cover member formed of a single layer of the first thin plate glass (200 μm) was used.

### Experimental Example 1: Exterior Characteristics and Transfer Characteristics

By illuminating surfaces of the display devices manufactured according to the Examples and the Comparative Examples with fluorescent light, it was visually confirmed whether a pattern such as orange peel was observed on the surface, and it was visually observed whether or not a folding boundary was transferred. The orange peel and a degree of transfer of the folding boundary that are visually observed were evaluated as weak-weak, weak, medium, medium-strong, and strong, and consequent results are shown in Table 1.

### Experimental Example 2: Impact Resistance Evaluation

In order to examine impact resistance characteristics of the display devices according to Examples and Comparative Examples, a ball drop test was performed on a folding area and a non-folding area according to a method specified in ASTM F3007. This was performed by dropping a metallic ball on the folding area and a bending area of the display device at different drop heights. While free-falling of the metallic ball was made, a limit height at which the display device was damaged by the metallic ball was measured. The results are shown in Table 1.

### Experimental Example 3: Folding Characteristics

Table 1 shows radii of curvature that can be implemented by the display devices according to Examples and Comparative Examples.

TABLE 1

| | | Examples | | | | Comparative Examples | | | |
|---|---|---|---|---|---|---|---|---|---|
| | | 1 | 2 | 3 | 4 | 1 | 2 | 3 | 4 |
| Exterior | | weak | weak | weak- | weak- | strong | strong | weak | weak- |
| characteristics | | | | weak | weak | | | | weak |
| Folding Boundary | | medium- | medium- | medium- | medium- | strong | medium- | medium- | weak- |
| Transfer | | strong | strong | strong | strong | | strong | strong | weak |
| Ball | Folding | 15 | 17.5 | 17.5 | 17.5 | 10 | 7.5 | 15 | 30 |
| Drop | Area | | | | | | | | |
| Test | (cm) | | | | | | | | |
| | Non- | 30 | 30 | 30 | 30 | 27.5 | 17.5 | 30 | 30 |
| | Folding | | | | | | | | |
| | Area | | | | | | | | |
| | (cm) | | | | | | | | |

| | | | | | | | | |
|---|---|---|---|---|---|---|---|---|
| Folding | 5R | 5R | 5R | 5R | — | 4R | 7R | 35R |
| characteristics (radius | | | | | | | | |
| of curvature) | | | | | | | | |

Referring to Table 1, in the cases of Examples 1 to 4 using the cover member including the plurality of thin glass plates, almost no unevenness such as orange peel was observed on the surface, and it could be confirmed that the folding boundary transfer was on a level equivalent to that of a conventional display device.

In addition, in the cases of Examples 1 to 4, it was confirmed that the impact resistance characteristics were excellent in both the folding area and the non-folding area and the folding characteristics were excellent, so that even a level of a curvature radius of 5R could be implemented.

On the contrary, in the case of Comparative Example 1, it was confirmed that the exterior characteristics were poor, a degree to which the folding boundary is visually recognized was also severe, and the folding characteristics were poor. Even in the case of Comparative Example 2, it was confirmed that the exterior characteristics were poor, and it could be confirmed that the impact resistance characteristics were half that of the Examples even though the folding characteristics were excellent by applying the single layer of the thin plate glass as the cover member. In the case of Comparative Example 3, it could be confirmed that the impact resistance is on the level equivalent to that of the Examples by using a thin plate glass having a larger thickness compared to the Examples, but the folding characteristics were relatively poor by applying the single layer of the thin plate glass. In addition, in the case of Comparative Example 4, it was confirmed that the flexible display device according to Comparative Example 4 was difficult to be implemented as a foldable display device due to very poor folding characteristics, although it was confirmed that the exterior characteristics thereof were excellent and the impact resistance was the most excellent by using the thin plate glass having a larger thickness.

Comparing the results of Example 3 and Comparative Example 4, in the case of Example 3, it was confirmed that the impact resistance was equivalent to that of Comparative Example 4 and the folding characteristics were very excellent although a total thickness of the cover member thereof was larger than that of Comparative Example 4, In addition, comparing the results of Example 2 and Comparative Example 3, it could be confirmed that the impact resistance was the same but the folding characteristics of Example 2 in which the total thickness of the cover member is larger than that of Comparative Example 3 were more excellent.

That is, it could be confirmed that when the cover member according to the present disclosure is applied, the surface and exterior characteristics can be maintained high, and the folding characteristics and the impact resistance can be improved at the same time, which are more advantageous for realizing a foldable display device.

### Experimental Example 4: Impact Resistance Evaluation According to Presence or Absence of Cushion Layer

In the flexible display devices according to Examples 1 to 4 and Comparative Examples 1 to 2, impact resistance according to presence or absence of a cushion layer was evaluated. In each of a case in which the cushion layer is present and a case in which the cushion layer is absent in the flexible display devices according to Examples 1 to 4 and Comparative Examples 1 to 2, a ball drop test was performed. The ball drop test was performed in the same manner as in Experimental Example 2 to measure a limit height, and the results are shown in Table 2 below.

TABLE 2

| | | | | | | Comparative | |
|---|---|---|---|---|---|---|---|
| | | Examples | | | | Examples | |
| | | 1 | 2 | 3 | 4 | 1 | 2 |
| Ball Drop Test | Folding | 3 | 3 | 3 | 3 | 3 | 3 |
| (without cushion | Area(cm) | | | | | | |
| layer) | Non- | 3 | 3 | 3 | 3 | 3 | 3 |
| | Folding | | | | | | |
| | Area(cm) | | | | | | |
| Ball Drop Test | Folding | 15 | 17.5 | 17.5 | 17.5 | 10 | 7.5 |
| (with cushion layer) | Area(cm) | | | | | | |
| | Non- | 30 | 30 | 30 | 30 | 27.5 | 17.5 |
| | Folding | | | | | | |
| | Area(cm) | | | | | | |

Referring to Table 2, it could be confirmed that when the ball drop test is carried out without the cushion layer, all of Examples 1 to 4 and Comparative Examples 1 to 2 exhibited the same impact resistance with the limit height of 3 cm, and it could be confirmed that in the case of including the cushion layer, the impact resistance was greatly improved in all of the Examples and the Comparative Examples. However, in the case of the Examples in which the thin glass plates are stacked and applied, it could be confirmed that a degree of improvement in impact resistance due to the introduction of the cushion layer was greater than that of the Comparative Examples.

Specifically, in the cases of Examples 1 to 4, it could be confirmed that due to the introduction of the cushion layer, the limit height for the folding area was 3 cm to 15 cm or 17.5 cm, which increased by 5 times or more, and the limit height for the non-folding area increased by about 10 times, so that the impact resistance was greatly increased. On the other hand, in the case of Comparative Example 1, it could be confirmed that due to the introduction of the cushion layer, the limit height in the folding area was 3 cm to 10 cm, which increased by about 3 times, and the limit height in the non-folding area increased by about 9 times, but the degree of improvement in impact resistance was not good compared to the Examples. In addition, in the case of Comparative Example 2, it could be confirmed that due to the introduction of the cushion layer, the limit height increased by about 2.5 times in the folding area and increased by about 5.5 times in the non-folding area, and the degree of improvement in impact resistance was insufficient compared to the Examples.

Incidentally, when a pen drop test was conducted using each of a low-weight pen and a heavy-weight pen instead of a metallic ball, results similar to those of the ball drop test were confirmed. When the pen drop test using a low-weight pen was performed in all of Examples 1 to 4 and Comparative Examples 1 to 2 with the introduction of the cushion layer, it could be confirmed that the limit height increased by about 7 times, and the impact resistance was improved. However, when the pen drop test was performed using a heavy-weight pen, it could be confirmed that the limit height hardly increased in the case of the Comparative Examples, whereas in Examples 1 to 4, the limit height increased by 2 times to 3 times even when the heavy-weight pen was used.

In summary, even in the case of Comparative Example 1 using the film-type cover member or Comparative Example 2 using the single layer of thin plate glass, it could be confirmed that the impact resistance was improved by the introduction of the cushion layer, but the degree of improvement in impact resistance was insufficient as compared to Examples 1 to 4 in which the thin glass plates are stacked to be used as the cover member.

As a result, it could be confirmed that the flexible display devices which use the cover member formed by stacking the thin glass plates and include the cushion layer can further maximize impact resistance while maintaining high folding characteristics due to their synergistic effect.

The exemplary aspects of the present disclosure can also be described as follows:

According to an aspect of the present disclosure, a flexible display device comprising a flexible substrate including a display area and a non-display area, an organic light emitting element disposed on the flexible substrate, and a cover member disposed on the organic light emitting element and including a plurality of thin glass plates and an adhesive layer between the plurality of thin glass plates, wherein each of the plurality of thin glass plates has a thickness of 0.1 mm or less.

Each of the plurality of thin glass plates may include an upper surface, a lower surface, and a side surface, and at least one thin plate glass of the plurality of thin glass plates may have a chamfered shaped at a corner thereof.

The thin plate glass having the chamfered shape further may include a first inclined portion connecting the upper surface and the side surface and inclined at a predetermined angle, and a second inclined portion connecting the lower surface and the side surface and inclined at a predetermined angle.

A linear distance from an end of the upper surface or lower surface of the thin plate glass to the side surface adjacent thereto may be 10 μm to 50 μm.

The cover member may include a first thin plate glass disposed on the organic light emitting element, a first adhesive layer disposed on the first thin plate glass, and a second thin plate glass disposed on the first adhesive layer.

A thickness of the second thin plate glass may be equal to or smaller than a thickness of the first thin plate glass.

The first adhesive layer may include a variable adhesive having adhesion that varies according to presence or absence of light irradiation, heat, or moisture.

The cover member further may include a second adhesive layer disposed on the second thin plate glass, and a third thin plate glass disposed on the second adhesive layer and having a thickness equal to or smaller than the thickness of the second thin plate glass.

The second adhesive layer may include a variable adhesive having adhesion that varies according to presence or absence of light irradiation, heat, or moisture.

At least one thin plate glass of the plurality of thin glass plates may be a chemically strengthened glass.

A thin plate glass disposed at an uppermost portion of the plurality of thin glass plates may include a shatter-resistant layer on at least one surface thereof.

The shatter-resistant layer may be formed to surround an upper surface, a lower surface, and both side surfaces of the thin plate glass.

The flexible display device may further comprise a black matrix layer disposed on at least one surface of a thin plate glass disposed at a lowermost portion of the plurality of thin glass plates to overlap the non-display area.

The flexible display device may further comprise a cushion layer below the flexible substrate.

According to another aspect of the present disclosure, a flexible display device comprising a flexible substrate including a display area and a non-display area, an organic light emitting element disposed on the flexible substrate, and a cover member disposed on the organic light emitting element and including a plurality of thin glass plates and an adhesive layer between the plurality of thin glass plates, wherein a thickness of a thin plate glass positioned at an uppermost portion of the plurality of thin glass plates is equal to or smaller than a thickness of a remaining thin plate glass.

The thickness of each of the plurality of thin glass plates may be 0.1 mm or less.

The thickness of the thin plate glass positioned at the uppermost portion of the plurality of thin glass plates may be 70 μm or less, and the thickness of the remaining thin plate glass may be 0.1 mm or less.

The adhesive layer may include a variable adhesive having adhesion that varies according to presence or absence of light irradiation, heat, or moisture.

The flexible display device may have a radius of curvature of 5R or less.

Each of the plurality of thin glass plates may have a chamfered shape at a corner thereof.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A flexible display device, comprising:
a flexible substrate including a display area and a non-display area;
an organic light emitting element disposed on the flexible substrate; and
a cover member disposed on the organic light emitting element and including a plurality of thin glass plates and an adhesive layer between the plurality of thin glass plates,
wherein each of the plurality of thin glass plates has a thickness of 0.1 mm or less.

2. The flexible display device of claim 1, wherein each of the plurality of thin glass plates includes an upper surface, a lower surface, and a side surface, and at least one thin glass plate of the plurality of thin glass plates has a chamfered shaped at a corner thereof.

3. The flexible display device of claim 2, wherein the thin glass plate having the chamfered shape further includes a first inclined portion connecting the upper surface and the side surface and inclined at a predetermined angle, and a second inclined portion connecting the lower surface and the side surface and inclined at a predetermined angle.

4. The flexible display device of claim 3, wherein a linear distance from an end of the upper surface or lower surface of the thin glass plate to the side surface adjacent thereto is 10 μm to 50 μm.

5. The flexible display device of claim 1, wherein the cover member includes a first thin glass plate disposed on the organic light emitting element, a first adhesive layer disposed on the first thin plate glass, and a second thin glass plate disposed on the first adhesive layer.

6. The flexible display device of claim 5, wherein a thickness of the second thin plate glass is equal to or smaller than a thickness of the first thin glass plate.

7. The flexible display device of claim 5, wherein the first adhesive layer includes a variable adhesive having adhesion that varies according to presence or absence of light irradiation, heat, or moisture.

8. The flexible display device of claim 5, wherein the cover member further includes a second adhesive layer disposed on the second thin glass plate, and a third thin glass plate disposed on the second adhesive layer and having a thickness equal to or smaller than the thickness of the second thin plate glass.

9. The flexible display device of claim 8, wherein the second adhesive layer includes a variable adhesive having adhesion that varies according to presence or absence of light irradiation, heat, or moisture.

10. The flexible display device of claim 1, wherein at least one thin glass plate of the plurality of thin glass plates is chemically strengthened.

11. The flexible display device of claim 1, wherein a thin glass plate disposed at an uppermost portion of the plurality of thin glass plates includes a shatter-resistant layer on at least one surface thereof.

12. The flexible display device of claim 11, wherein the shatter-resistant layer is formed to surround an upper surface, a lower surface, and both side surfaces of the thin glass plate.

13. The flexible display device of claim 1, further comprising a black matrix layer disposed on at least one surface of a thin glass plate disposed at a lowermost portion of the plurality of thin glass plates to overlap the non-display area.

14. The flexible display device of claim 1, further comprising a cushion layer below the flexible substrate.

15. A flexible display device, comprising:
a flexible substrate including a display area and a non-display area;
an organic light emitting element disposed on the flexible substrate; and
a cover member disposed on the organic light emitting element and including a plurality of thin glass plates and an adhesive layer between the plurality of thin glass plates,
wherein a thickness of a thin glass plate positioned at an uppermost portion of the plurality of thin glass plates is equal to or smaller than a thickness of a remaining thin glass plate.

16. The flexible display device of claim 15, wherein the thickness of each of the plurality of thin glass plates is 0.1 mm or less.

17. The flexible display device of claim 16, wherein the thickness of the thin glass plate positioned at the uppermost portion of the plurality of thin glass plates is 70 μm or less, and the thickness of the remaining thin glass plate is 0.1 mm or less.

18. The flexible display device of claim 15, wherein the adhesive layer includes a variable adhesive having adhesion that varies according to presence or absence of light irradiation, heat, or moisture.

19. The flexible display device of claim 15, wherein the flexible display device has a radius of curvature of 5R or less.

20. The flexible display device of claim 15, wherein each of the plurality of thin glass plates has a chamfered shape at a corner thereof.
